(19) United States
(12) Patent Application Publication
(10) Pub. No.: US 2008/0211061 A1
(43) Pub. Date: Sep. 4, 2008

(54) Method For the Fabrication of GaAs/Si and Related Wafer Bonded Virtual Substrates

(75) Inventors: Harry A. Atwater Jr, South Pasadena, CA (US); James M. Zahler, Pasadena, CA (US)

Correspondence Address: Hiscock & Barclay, LLP, One Park Place, 300 South State Street, Syracuse, NY, 13202-2078, US

(73) Assignee: CALIFORNIA INSTITUTE of TECHNOLOGY, Pasadena, CA (US)

(21) Appl. No.: 11/587,044

(22) PCT Filed: Apr. 21, 2005
(86) PCT No.: PCT/US05/13609

§ 371 Date: Sep. 12, 2007

Related U.S. Application Data
(60) Provisional application No. 60/564,251, filed on Apr. 21, 2004.

(51) Int. Cl. H01L 29/20; H01L 21/18

(52) U.S. Cl. 257/615; 438/458; 257/E29.089; 257/E21.088

(57) ABSTRACT

A method of making a virtual substrate includes providing a device substrate of a first material containing a device layer of a second material different from the first material located over a first side of the device substrate, implanting ions into the device substrate such that a damaged region is formed in the device substrate below the device layer, bonding the device layer to a handle substrate, and separating at least a portion of the device substrate from the device layer bonded to the handle substrate along the damaged region to form a virtual substrate comprising the device layer bonded to the handle substrate.

### CROSS-REFERENCE TO RELATED PATENT APPLICATIONS

This application claims the benefit of U.S. Provisional Application 60/564,251, filed Apr. 21, 2004, incorporated herein by reference in its entirety.

### BACKGROUND OF THE INVENTION

The present invention relates generally to the field of semiconductor processing and specifically to wafer bonded virtual substrates and methods of making thereof.

Silicon on insulator wafer bonded virtual substrates have been made by bonding a silicon device wafer to an insulating handle substrate and then removing a portion of the silicon device wafer to form a virtual substrate comprising a silicon film on an insulating substrate. For example, hydrogen ions are implanted into a silicon device wafer to create a damaged layer below the surface of the silicon device wafer. The silicon device wafer is then bonded to a dissimilar handle substrate, such as a glass or plastic insulating handle substrate. The device wafer is then annealed to split the device wafer along the damaged region to leave a thin silicon film bonded to the handle substrate to form the virtual silicon on insulator substrate. The remaining device wafer is then usually discarded.

The above method may be used to form silicon on insulator virtual substrates. However, the above method may be more expensive than desired for compound semiconductor virtual substrates due to the cost of certain compound semiconductor wafers which function as the device wafer. Furthermore, certain compound semiconductor materials, such as certain ternary and quaternary compound semiconductor materials cannot be made into a single crystal wafer. Thus, they cannot function as a device wafer in the wafer bonding process to form a compound semiconductor virtual substrate. Thus, a method of making a virtual substrate at a reduced cost and/or containing a thin film of materials which cannot be formed into a single crystal wafer is desirable.

### SUMMARY OF THE INVENTION

One embodiment of the invention provides a method of making a virtual substrate, which includes providing a device substrate of a first material containing a device layer of a second material different from the first material located over a first side of the device substrate, implanting ions into the device substrate such that a damaged region is formed in the device substrate below the device layer, bonding the device layer to a handle substrate, and separating at least a portion of the device substrate from the device layer bonded to the handle substrate along the damaged region to form a virtual substrate comprising the device layer bonded to the handle substrate.

### BRIEF DESCRIPTION OF THE DRAWINGS

FIG. 1a is a side cross-sectional view of a diagram of a device substrate prior to processing.

FIG. 1b is a side cross-sectional view of a diagram of a device layer grown or disposed on the device substrate.

FIG. 2 is a side cross-sectional view of a diagram of device substrate containing an etch stop layer between the device layer and the device substrate.

FIG. 3a is a side cross-sectional view of a diagram of ion implantation through the device layer into the device substrate.

FIG. 3b is a side cross-sectional view of a diagram of the device substrate following implantation, showing the device layer and the implantation-induced damaged region in the device substrate.

FIG. 4a is a side cross-sectional view of a diagram of the bonded device substrate and handle substrate structure illustrating the bonded interface between the device layer and the handle substrate.

FIG. 4b is a side cross-sectional view of a diagram of the bonded structure following annealing and layer transfer illustrating the separation of the device substrate along the damaged region.

FIG. 5a is a side cross-sectional view of a diagram of the bonded structure following the separation of the device substrate.

FIG. 5b is a side cross-sectional view of a diagram of the virtual substrate following the removal of the residual damaged region and remaining portion of the device substrate leaving only the device layer bonded to the handle substrate.

FIG. 6a is a side cross-sectional view of a diagram of the separated portion of the device substrate following the separation step.

FIG. 6b is a side cross-sectional view of a diagram of the separated portion of the device substrate following a reclamation process to enable reuse of this portion of the substrate to transfer another epitaxial device layer:

### DETAILED DESCRIPTION OF THE PREFERRED EMBODIMENTS

The present inventors realized that instead of exfoliating a portion of a device wafer to form a virtual substrate comprising a device film on a handle substrate, a device substrate of one material with a layer of another material different from the substrate material can be used to form the virtual substrate. For example, the layer may comprise a material which is expensive and/or is not available in wafer form, while the device substrate may comprise a less expensive material and/or a material which is available in wafer or substrate form. Preferably, the layer comprises a single crystal layer which is expitaxially formed over the device substrate (i.e., either directly on or over an intermediate layer on the device substrate). The single crystal device layer may be formed over the device substrate by any suitable epitaxial deposition method, such as CVD, MBE, LPE, sputtering, etc.

Thus, a preferred method of making a virtual substrate includes the following steps. First, a device substrate containing a device layer of a material different from the device substrate material is provided. The device layer is provided over one side of the device substrate.

Second, ions are implanted into the device substrate such that a damaged region is formed in the device substrate below the device layer. For example, hydrogen and/or noble gas ions, such as helium, are implanted into the device substrate. Preferably, the ions are implanted through the device layer to form the damaged region in the upper part of the device substrate slightly below the device layer. It should be noted that if the device substrate is relatively thin, then the ions may be implanted through the lower side (i.e., the side opposite from the side supporting the device layer) of the device substrate. In this case, ion implantation damage to the device layer is avoided. The ion implantation depth is calculated such that the damaged region is located below the device layer.

Third, the device layer is bonded to a handle substrate. In other words, the upper side of the device layer is bonded to a handle substrate, while the lower side of the device layer remains attached to the device substrate which contains the damaged region. Any suitable bonding method may be used. Exemplary bonding steps are described in more detail below. It should be noted that the terms “upper” and “lower” are relative terms used for convenience to describe the relationship between the device substrate and the device layer. If the device substrate is turned upside down or sideways, the device layer would not be located on “top” of the device substrate.

Fourth, at least a portion of the device substrate is separated from the device layer while the device layer is bonded to the handle substrate. The device layer is separated along the damaged region to form a virtual substrate comprising the device layer bonded to the handle substrate.

The device layer may comprise any suitable semiconductor or other material, such as a compound semiconductor layer, for example a III-V, II-VI, IV-IV or I-III-VI layer. The compound semiconductor layer may comprise a binary, ternary, quaternary or five component compound semiconductor layer. Examples of III-V compound semiconductor layers include arsenide, phosphide and/or nitride layers, such as GaAs, AlGaAs, InGaAs, InGaAlAs, GaP, InGaP, AlGaP, GaN, InGaN, InGaAlN, AlGaN, GaAsP, InGaAsP, AlGaAsP, InGaAlAsP, etc. Examples of II-VI compound semiconductor layers include ZnSe, ZnTe, CdSe, CdTe, ZnTeSe, ZnCdSe, etc. Examples of IV-IV compound semiconductor layers include SiC. Examples of I-III-VI semiconductor layers include CuInSe and CuInGaSe. Other compound semiconductor layers, such as PbS, ZnS, ZnO, etc. may also be used. The device layer 2 may be intrinsic (i.e., undoped), doped p-type or n-type during growth or after growth by ion implantation or diffusion.

Any suitable device substrate may be used. Preferably, the device substrate comprises a material over which the device layer may be epitaxially grown, either directly or using a graded buffer layer. Examples of device substrate material include single crystal semiconductor wafers or substrates, or single crystal ceramic material, such as sapphire, which support epitaxial growth of the device layer. For example, a Ge substrate (i.e., wafer or other substrate) may be used to epitaxially form arsenide or phosphide Ill-V layers, such as GaAs, InGaP, AlGaAs, etc. A sapphire substrate may be used for IV-IV and nitride III-V layers, such as GaN and InGaN. A binary III-V substrate, such as a GaAs substrate or wafer may be used for ternary or quaternary III-V or II-VI layers, such as InGaAs, which are either more expensive or which are not available in wafer form.

Any suitable handle substrate may be used. The handle substrate may comprise a conducting material which acts as an electrode of a device, a semiconductor material which acts as one of the semiconductor or active layers of a device, or an insulating material which acts as a support or insulation of the device. For example, the handle substrate may comprise a silicon substrate (i.e., a silicon wafer or other silicon substrate), an insulator on silicon substrate, such as a silicon oxide or nitride covered silicon substrate, a compound semiconductor substrate, a metal or conductive oxide (such as ITO) substrate (or another substrate covered with a metal or conductive oxide layer), or an insulating substrate, such as a ceramic, glass, quartz, or plastic substrate.

Optionally, a lattice matched etch stop layer is located between the device layer and the device substrate. The etch stop layer may be any layer which allows epitaxial growth of the device layer over it and which can be selectively etched compared to the device layer. When the device substrate is separated, the remaining portions of the damaged region and the device substrate are removed by etching or polishing with a first selected etching or polishing medium which preferentially etches or polishes the device substrate to the etch stop layer. Thus, since etch stop layer has a lower etching or polishing rate than the device substrate, the etch or polish stops on the etch stop layer. Thereafter, the etch stop layer is selectively removed by etching or polishing by using a second etching or polishing medium which preferentially etches or polishes the etch stop layer compared to the device layer. Thus, the removal of the etch stop layer stops on the device layer, thus leaving a smooth, abrupt device layer surface with low damage. Therefore, the virtual substrate contains the device layer with a high quality exposed surface on which additional epitaxial device layers may be grown. Examples of the etch stop layer include an InGaP or an AlGaAs layer located between a Ge substrate and a GaAs device layer. Other compound semiconductor etch stop layers may be used for other compound semiconductor device layers.

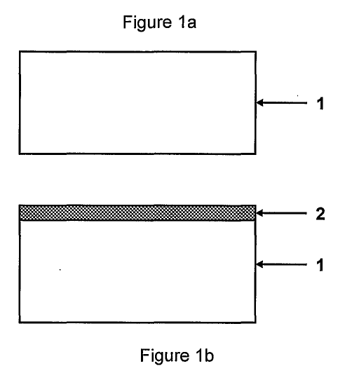

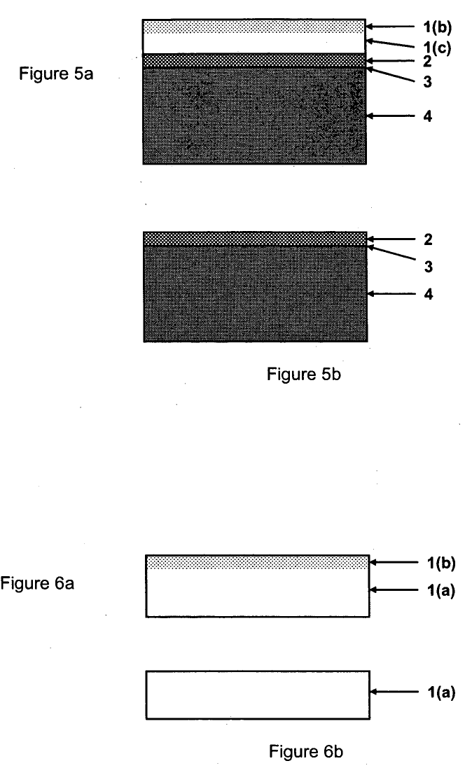

Embodiments of forming the virtual substrate are described below. FIG. 1a illustrates a device substrate (i.e., wafer or other substrate) 1 prior to processing. FIG. 1b illustrates the device substrate 1 with the epitaxial device layer 2 located over the “upper” surface of the substrate 1. For example, the substrate 1 may comprise a Ge wafer and the device layer 2 may comprise an epitaxial GaAs layer. The thickness of the device layer 2 can be selected to control the thickness of the device film or layer 2 on the finished virtual substrate shown in FIG. 5b.

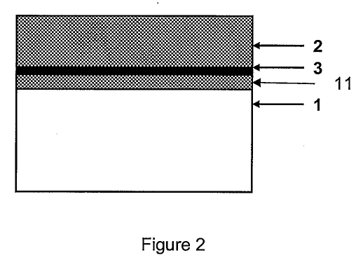

FIG. 2 illustrates an alternative embodiment, where a lattice matched etch stop layer 3 is provided between the device substrate 1 and the device layer 2. As described above, the etch stop layer 3 may comprise an epitaxial compound semiconductor layer that is grown over the substrate 1, and the device layer is a different compound semiconductor layer that is epitaxially grown over the etch stop layer 3. The etch stop layer 3 allows the achievement of a well defined structure surface and thickness of the device layer 2 on the completed virtual substrate. For example, InGaP and AlGaAs etch stop layers over a Ge substrate allow formation of a virtual substrate with a smooth, abrupt GaAs surface. If desired, one or more optional intermediate or buffer layers 11 may be located between the device substrate 1 and the etch stop layer 3 and/or between the etch stop layer 3 and the device layer 2, as shown in FIG. 2.

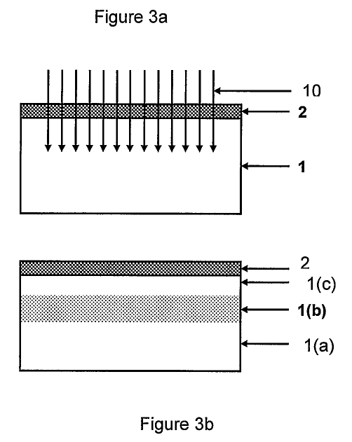

The method continues with implanting the device substrate 1 through layer 2 with an optimized dose and energy combination of ions 10, such as H⁺ or H⁺/He⁺ as diagrammatically depicted in FIG. 3a. The implant energy will be selected to ensure that the damaged region 1b of the implantation occurs predominantly in the Ge substrate 1 away from the Ge/GaAs interface between region 1c and layer 2 as diagrammatically depicted in FIG. 3b. Region la denotes the portion of device substrate 1 which is substantially unchanged. Region 1c denotes the portion of device substrate 1 located between the damaged region 1b and the device layer 2. The ion dose at a given energy can be optimized as a function of substrate temperature during implant.

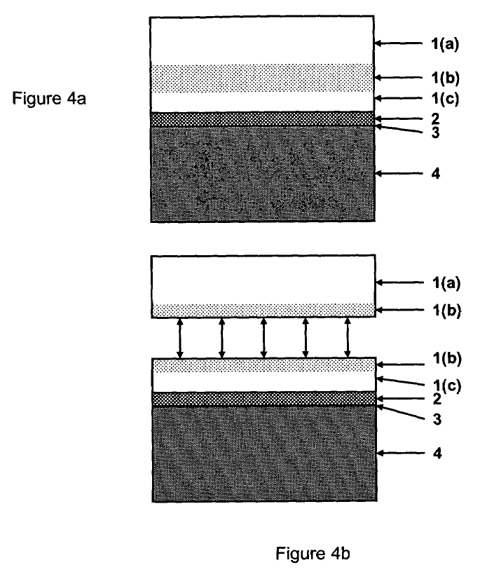

The GaAs device layer 2 carried on the Ge device substrate 1 is bonded or transferred to a prepared handle substrate 4, such as a Si handle substrate, as will be described in connection with FIGS. 4a and 4b. Wet and/or dry chemical passivation processes are preferably first employed to activate the bonding surfaces of both the GaAs device layer 2 and the Si handle substrate 4. Hydrophobic surface passivation and hydrophilic surface passivation processes can be used as described below.

The hydrophobic surface passivation is utilized to arrive at an abrupt, electrically-conducting bonded interface between the device layer 2 and the handle substrate 4. Thus, in this embodiment of the invention, the handle substrate preferably comprises a conductive or semiconductor substrate, such that current can flow between the device layer 2 and the handle substrate 4 in the completed device. The hydrophobic surface passivation of one or both of the device layer 2 and the handle substrate 4 may be carried out by one more of the following process steps. Dilute HF is a good hydrophobically passivating etch for Si, while HCl hydrophobically passivates GaAs and for the extended family of GaAs based ternaries and quaternaries. Thus, the device layer 2 may be passivated by HF while the handle substrate 4 may be passivated by HCl. Other wet chemical etches which leave a predominantly hydrogen passivated surface may also be used. Alternatively, dry chemical etching with an inert atmosphere, such as argon, that sputters away oxidized surface material may also be used to render the surfaces hydrophobic. Dry chemical etching with a reactive gas, such as a hydrogen plasma, also chemically removes oxides from both the Si and GaAs substrates, and can be used for hydrophobic passivation.

In contrast, hydrophilic passivation may be used to form an insulating interface between the handle substrate 4 and the device layer 2. Thus, hydrophilic passivation provides a strongly bonded substrate/device layer structure that is comprised of an electrically isolated GaAs film on a Si or other substrate. Specifically, hydrophilic passivation provides an oxide on the bonding surface of the device layer 2 and/or the handle substrate 4 which provides a strong bond and an insulating interface.

NH₄OH:H₂O₂:H₂O solutions are well known to produce a chemical oxide on Si, and may be used to hydrophilically passivate the handle substrate. H₂SO₄:H₂O₂ etching solutions produce an oxide on GaAs, and may be used to hydrophilically passivate the device layer. Either one or both of the above passivation steps may be used prior to bonding (i.e., either one or both of the device layer and the handle substrate may be passivated). Alternatively, ultra-violet ozone treatment of both GaAs and Si can be utilized to produce a thin surface oxide with little or no roughening of the surface. In this treatment, the surfaces are treated with ozone gas under UV radiation. Dry etch plasma processes in oxygen plasmas produce chemically activated surface oxides for both Si and GaAs and can also be used for hydrophilic passivation.

If desired, an optional bonding layer is deposited on one or both of the device layer 2 and the handle substrate 4. A bonding layer is any material layer which enhances the bonding between the device layer and the handle substrate. For example, an amorphous silicon bonding layer may be deposited on the GaAs device layer 2 to enhance the bond to the handle substrate (i.e., to form a bond between amorphous silicon and silicon dioxide formed by hydrophilic passivation on the handle substrate, or a direct silicon to silicon bond if the handle substrate lacks the silicon oxide layer).

After the passivation, bonding between the handle substrate 4 and the device film is initiated as shown in FIG. 4a. The bonding may be conducted at a room or at an elevated temperature while pressing the device layer 2 and the handle substrate 4 together under pressure. The bonding temperature may be selected to engineer the strain state of the device layer 2. As was previously described in U.S. patent application Ser. No. 10/784,586, incorporated by reference herein in its entirety, for the case of Δ α(T)<0, the device layer 2 is under compression, (where Δ α(T) is the difference in coefficients of thermal expansion of the device layer 2 and the handle substrate 4) and the elevated temperature bonding has the following effect. The device layer 2 has a zero strain condition at the bonding temperature such that compressive strain and convex bowing will be reduced at higher processing temperatures. Likewise, the device layer 2 is in tensile strain at room temperature and likely at device operating temperatures to lead to concave virtual substrate bow. This could change device operation and enable design of novel devices based on strain control of materials parameters. Some materials of interest for the wafer bonded virtual substrates described herein belong to this category of materials. If desired, the device layer 2 and the handle substrate 4 may be maintained at different temperatures during bonding initiation, as described in U.S. patent application Ser. No. 10/784,586.

The application of a pressure-temperature cycle, such as the cycle described in U.S. patent application Ser. No. 10/784,586 initiates the separation of the device substrate 1 to transfer of the GaAs epitaxial film 2 along with a thin portion 1a of the Ge device substrate 1 as shown in FIG. 4b. The temperature and pressure separate the device substrate 1 along the damaged region 1b. This can be performed in one of several ways: annealing under an optimized temperature-pressure cycle, annealing under constant pressure with constant temperature, or annealing without the application of pressure. If desired, the separation of the device substrate 1 may be assisted by mechanically pulling the substrate 1 apart or by using a separating blade or tool.

After the separation of the device substrate 1, a material selective, chemical mechanical polishing or chemical etching (or polishing) is used to remove the portions of the Ge device substrate 1b, 1c still adhered to the GaAs device layer 2 leaving a thin, single-crystal GaAs device layer or film 2 bonded to a Si handle substrate 4 as shown in FIG. 5b.

For example, modest etch rates can be achieved for germanium using a 30% H₂O₂:H₂O etch composition. This etch forms a stable oxide in GaAs that prevents further etching. This can be used to remove the residual portions 1b, 1c of Ge device substrate 1 from the GaAs device layer 2. Other etching and polishing media can be used for different device substrates. For example, for an InP device substrate, HCl:H₃PO₄:H₂O₂ etching liquid in any suitable ratio, such as 1:2:2 to 1:2:4 may be used. Likewise, chemical mechanical polishing media, such as colloidal silica slurry in KOH or sodium hypochlorite can be used to polish away the remaining portions 1b, 1c of Ge and InP device substrates, respectively.

The bonded device layer 2 on the handle substrate 4 shown in FIG. 5b constitutes the virtual substrate. The virtual substrate can be used for epitaxial deposition of additional compound semiconductor layer or layers on the device layer 2, as well as the deposition of conductive or insulating layers directly on or over the device layer 2.

As described above in connection with FIG. 2, further refinement of the device layer 2 thickness can be performed by providing an etch stop layer between the device layer 2 and device substrate 1, such as an AlGaAs or GaInP etch stop layer 3 for a GaAs device layer 2 on a Ge substrate 1. Growing of a thin InGaP layer 3 on the Ge device substrate 1 allows later selective removal of the InGaP layer 3 with NH₄OH:H₂O₂:H₂O following the separation and removal of the device substrate in FIG. 4b to leave a smooth, abrupt GaAs surface 2. Growing a thin AlGaAs structure or layer 3 on the Ge device substrate 1 also forms a smooth, abrupt etch stop layer that can be selectively removed with a citric-acid:H₂O₂ solution following the separation and removal of the device substrate in FIG. 4b to leave a smooth, abrupt GaAs surface 2. In other words, the remaining device substrate portions 1b, 1c are first removed by etching or polishing described above, which stops on the etch stop layer 3. Then, the etch stop layer 3 is removed, such as by the above described selective etching or polishing, which stops on the device layer 2, to expose a smooth, abrupt device layer surface suitable for epitaxial growth of additional semiconductor layers.

The separated device substrate portion la can be reclaimed by a subsequent wafer repolish, if desired. A new device layer 2 is then deposited on the repolished device substrate 1, and then used to form another virtual substrate. Thus, the process described above can be repeated a multiple number of times. This enables the possibility of transferring many films from a single device substrate 1 as depicted in FIG. 6.

There is a considerable advantage in being able to incorporate compound semiconductor layers or thin films, such as GaAs thin films on Si and other substrates to serve as virtual substrates. Such virtual substrates incorporate the desirable properties of Si, namely high thermal conduction, low density, superior mechanical toughness and low cost, with the optoelectronic properties of compound semiconductors, such as GaAs, GaP and GaN and their ternaries and quaternaries, namely high carrier mobilities and/or direct band-gap for radiation (UV, visible and/or IR) emission and/or detection. Such a III-V on Si, such as GaAs/Si virtual substrate could serve as a substrate for many high value applications, including but not limited to power amplifiers, multi-junction solar cells, heterojunction bipolar transistors (HBTs), HEMTs, while leading to breakthroughs in device design allowing the integration of traditional Si based logic devices with integrated light generation and detection systems, or power amplifiers integrated directly with digital signal processors for cell phones.

For example, the compound semiconductor light emitting device located in compound semiconductor layer(s), such as a laser or LED, may be used as an optical interconnect between different silicon based devices located in the silicon handle substrate, such as transistors or multi-device silicon based blocks, including logic or memory blocks. Alternatively, the silicon based devices, such as FETs or bipolar transistors may be used as switches or control logic for light emitting devices, such as lasers or LEDs (such as gallium nitride based lasers or LEDs), photodetectors or solar cells, such as Cu-In-Se or III-V based single junction or multi-junction solar cells.

Thus, the handle substrate 4 is not necessarily an unprocessed silicon wafer. The handle substrate may contain silicon devices, such as transistors, or portions of multi-junction solar cells already provided thereon or therein. Thus, the handle substrate may comprise a multilayer structure as well as a bare silicon wafer, as needed, prior to bonding to the device layer.

The foregoing description of the invention has been presented for purposes of illustration and description. It is not intended to be exhaustive or to limit the invention to the precise form disclosed, and modifications and variations are possible in light of the above teachings or may be acquired from practice of the invention. The description was chosen in order to explain the principles of the invention and its practical application. It is intended that the scope of the invention be defined by the claims appended hereto, and their equivalents.

What is claimed is:

1. A method of making a virtual substrate, comprising:
providing a device substrate of a first material containing a device layer of a second material different from the first material located over a first side of the device substrate;
implanting ions into the device substrate such that a damaged region is formed in the device substrate below the device layer;
bonding the device layer to a handle substrate; and
separating at least a portion of the device substrate from the device layer bonded to the handle substrate along the damaged region to form a virtual substrate comprising the device layer bonded to the handle substrate.

2. The method of claim 1, wherein the device layer comprises a single crystal layer which is epitaxially grown over the device substrate.

3. The method of claim 2, wherein the ions are implanted through the device layer into the device substrate.

4. The method of claim 2, wherein the ions comprise at least one of hydrogen or helium ions.

5. The method of claim 2, wherein the step of bonding comprises bonding at an elevated temperature.

6. The method of claim 2, wherein the step of separating comprises at least one of thermal or mechanical separating.

7. The method of claim 2, further comprising passivating a bonding surface of at least one of the device layer or the handle substrate prior to the step of bonding.

8. The method of claim 7, wherein the step of passivating comprises hydrophilically passivating at least one of the device layer or the handle substrate to form an insulating interface between the device layer and the handle substrate.

9. The method of claim 7, wherein the step of passivating comprises hydrophobically passivating at least one of the device layer or the handle substrate to form a conducting interface between the device layer and the handle substrate.

10. The method of claim 2, further comprising removing a remaining portion of the device substrate connected to the device layer after the step of separating to expose a surface of the device layer in the virtual substrate.

11. The method of claim 10, further comprising an etch stop layer located between the device substrate and the device layer.

12. The method of claim 11, wherein the step of removing a portion of the device substrate comprises selectively etching or polishing the remaining portion of the device substrate to expose the etch stop layer using a first etching or polishing medium.

13. The method of claim 12, further comprising selectively etching or polishing the etch stop layer to expose the device layer using a second etching or polishing medium different from the first etching or polishing medium.

14. The method of claim 2, further comprising polishing a separated portion of the device substrate and forming a second device layer on the polished separated portion of the device substrate.

15. The method of claim 2, wherein the device layer comprises a compound semiconductor layer.

16. The method of claim 15, wherein the compound semiconductor layer is selected from a group consisting of III-V, II-VI, I-III-VI or IV-IV semiconductor layers.

17. The method of claim 16, wherein the compound semiconductor layer is selected from a group consisting of binary, ternary or quaternary semiconductor layers.

18. The method of claim 16, wherein the device layer comprises GaAs, the handle substrate comprises Si and the device substrate comprises Ge.

19. The method of claim 16, wherein the device layer is selected from a group consisting of III-V nitride semiconductor layers.

20. The method of claim 19, wherein the device layer comprises a ternary or quaternary III-V semiconductor layer and the handle substrate comprises Si.

21. A method of making a semiconductor device, comprising:
providing a device substrate of a first material containing a device layer of a second material different from the first material located over a first side of the device substrate;
implanting ions into the device substrate such that a damaged region is formed in the device substrate below the device layer;
bonding the device layer to a handle substrate;
separating at least a portion of the device substrate from the device layer bonded to the handle substrate along the damaged region to form a virtual substrate comprising the device layer bonded to the handle substrate; and
forming a semiconductor device on the virtual substrate.

22. The method of claim 21, wherein the device is selected from a group consisting of a transistor, a solar cell, a photodetector, a laser or a light emitting diode.

23. The method of claim 22, wherein the device layer comprises a compound semiconductor layer.

24. The method of claim 23, wherein the handle substrate comprises a silicon substrate.

25. The method of claim 24, wherein a second semiconductor device is located on or in the silicon substrate.

26. A semiconductor device made by the method of claim 21.
